(19) United States
(12) Patent Application Publication
(10) Pub. No.: US 2026/0040808 A1
(43) Pub. Date: Feb. 5, 2026

(54) DISPLAY DEVICE

(71) Applicant: Samsung Display Co., LTD., Yongin-si (KR)

(72) Inventors: Hwan Young JANG, Yongin-si (KR); Kyu Young CHOI, Yongin-si (KR); So Woon KIM, Yongin-si (KR)

(73) Assignee: Samsung Display Co., LTD., Yongin-si (KR)

(21) Appl. No.: 19/082,549

(22) Filed: Mar. 18, 2025

(30) Foreign Application Priority Data
Aug. 5, 2024 (KR) 10-2024-0103719

(51) Int. Cl. H10K 71/00; H10K 59/131; H10K 59/88

(52) U.S. Cl. CPC H10K 71/861; H10K 59/131; H10K 59/88

(57) ABSTRACT

A display device includes a first anode electrode and a second anode electrode on a substrate, a first light emitting layer on the first anode electrode and a second light emitting layer on the second anode electrode, a common electrode on the first light emitting layer and the second light emitting layer, a first connection electrode connected to the first anode electrode, a second connection electrode connected to the second anode electrode, a first repair line overlapping the first connection electrode in a plan view, and a second repair line overlapping the second connection electrode in a plan view. The first repair line and the second repair line are disposed on different layers.

### CROSS-REFERENCE TO RELATED APPLICATION(S)

This application claims priority to and benefits of Korean Patent Application No. 10-2024-0103719 under 35 U.S.C. 119, filed on Aug. 5, 2024, in the Korean Intellectual Property Office (KIPO), the entire contents of which are incorporated herein by reference.

### BACKGROUND

### 1. Technical Field

The disclosure relates to a display device capable of preventing static electricity between repair lines.

### 2. Description of the Related Art

The organic light emitting diode display may have a reduced thickness and weight, because the organic light emitting diode display has self-light emitting characteristics, and does not require a separate light source unlike the liquid crystal display. In addition, the organic light emitting diode display is attracting attention as the next-generation display device for TVs, monitors, and portable electronic devices, because the organic light emitting diode display has high-quality characteristics such as low power consumption, high luminance, and high response speed.

### SUMMARY

Aspects of the disclosure provide a display device capable of preventing static electricity between repair lines.

According to an embodiment of the disclosure, a display device may include a first anode electrode and a second anode electrode on a substrate, a first light emitting layer on the first anode electrode and a second light emitting layer on the second anode electrode, a common electrode on the first light emitting layer and the second light emitting layer, a first connection electrode connected to the first anode electrode, a second connection electrode connected to the second anode electrode, a first repair line overlapping the first connection electrode in a plan view, and a second repair line overlapping the second connection electrode in a plan view. The first repair line and the second repair line may be disposed on different layers.

The display device may further include an insulating layer between the first repair line and the second repair line.

In a plan view, an end portion of the first repair line and an end portion of the second repair line may face each other.

The first repair line may be disposed closer to the substrate than the second repair line.

A distance between the substrate and the second repair line may be greater than a distance between the substrate and the first repair line.

A number of insulating layers between the substrate and the second repair line may be greater than a number of insulating layers between the substrate and the first repair line. In a plan view, the first repair line and the second repair line may not overlap.

In an area the first repair line and the first connection electrode overlap each other in a plan view, the first repair line and the first connection electrode may be connected to each other.

In an area the second repair line and the second connection electrode overlap each other in a plan view, the second repair line and the second connection electrode may be connected to each other.

At least one of an end portion of the first repair line and an end portion of the second repair line may have a round shape.

In a plan view, the end portion of the first repair line may have a round shape that convexly protrudes toward the end portion of the second repair line.

In a plan view, the end portion of the second repair line may have a round shape that convexly protrudes toward the end portion of the first repair line.

The display device may further include a first dummy pixel connected to the first repair line.

The first dummy pixel may be disposed in a non-display area of the substrate.

The first repair line may be disposed in a display area of the substrate, the first repair line may extend to the non-display area of the substrate, and the first repair line may be connected to the first dummy pixel in the non-display area of the substrate.

The display device may further include a first dummy data line connected to the first dummy pixel.

The first dummy pixel may not include a light emitting element.

The display device may further include a second dummy pixel connected to the second repair line.

The second dummy pixel may be disposed in a non-display area of the substrate.

The second repair line may be disposed in a display area of the substrate, the second repair line may extend to the non-display area of the substrate, and the second repair line may be connected to the second dummy pixel in the non-display area of the substrate.

According to an embodiment of the disclosure, an electronic device may include a display device that provides an image, and a processor that transmits an image data signal to the display device. The display device may include a first anode electrode and a second anode electrode on a substrate, a first light emitting layer on the first anode electrode and a second light emitting layer on the second anode electrode, a common electrode on the first light emitting layer and the second light emitting layer, a first connection electrode connected to the first anode electrode, a second connection electrode connected to the second anode electrode, a first repair line overlapping the first connection electrode in a plan view, and a second repair line overlapping the second connection electrode in a plan view. The first repair line and the second repair line may be disposed on different layers.

According to the display device according to the disclosure, since the first repair line and the second repair line are disposed on different layers so that an end portion of the first repair line and an end portion of the second repair line do not face each other, static electricity may be prevented from being generated between the end portion of the first repair line and the end portion of the second repair line. Therefore, damage to the repair lines due to the static electricity may be prevented.

However, effects according to the embodiments of the disclosure are not limited to those exemplified above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view illustrating a display device according to an embodiment;

FIG. 2 is a schematic plan view illustrating a display panel of FIG. 1;

FIG. 3 is a schematic plan view of the display panel of FIG. 1;

FIG. 4 is a schematic diagram of an equivalent circuit of a first pixel according to an embodiment;

FIG. 5 is a schematic diagram of an equivalent circuit of a first dummy pixel according to an embodiment;

FIG. 6 is a schematic diagram of an equivalent circuit for describing a method for repairing a defective pixel according to an embodiment;

FIG. 7 is a schematic diagram illustrating a planar array of the display device according to an embodiment;

FIG. 8 is a schematic cross-sectional view taken along line I-I′ of FIG. 7;

FIG. 9 is a schematic diagram of the display device manufactured according to the repair method according to an embodiment;

FIG. 10 is a schematic cross-sectional view taken along line II-II′ of FIG. 9; and

FIG. 11 is a schematic diagram of the display device according to an embodiment.

FIG. 12 is a block diagram of an electronic device according to one embodiment.

FIGS. 13, 14 and 15 are schematic diagrams of electronic devices according to various embodiments.

### DETAILED DESCRIPTION OF THE EMBODIMENTS

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

The same reference numbers indicate the same components throughout the specification. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Features of various embodiments of the disclosure may be combined partially or totally. As will be clearly appreciated by those skilled in the art, technically various interactions and operations are possible. Various embodiments can be practiced individually or in combination.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments will be described with reference to the accompanying drawings.

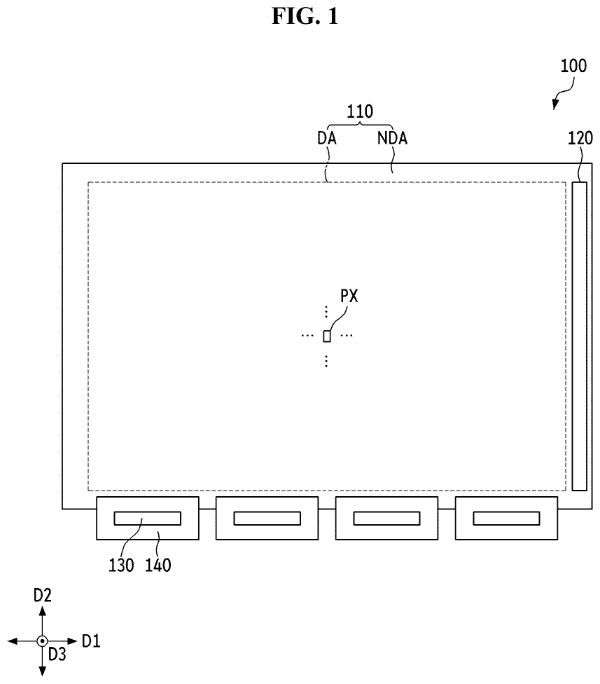

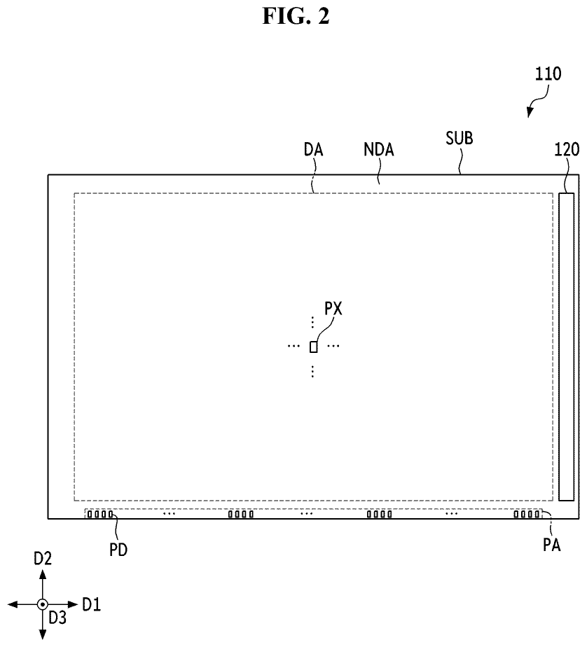

FIG. 1 is a schematic plan view illustrating a display device 100 according to an embodiment. FIG. 2 is a schematic plan view illustrating a display panel 110 of FIG. 1.

Referring to FIGS. 1 and 2, the display device 100 may display a moving image or a still image, and may be used as a display screen of various products such as a television, a laptop computer, a monitor, a billboard, and an Internet of Things (IOT) device as well as portable electronic devices such as a mobile phone, a smartphone, a tablet personal computer (PC), a smartwatch, a watch phone, a mobile communication terminal, an electronic organizer, an electronic book, a portable multimedia player (PMP), a navigation device, and an ultra mobile PC (UMPC). However, the disclosure is not limited thereto, and the display device 100 may also be employed in other electronic devices.

In an embodiment, the display device 100 may be a light emitting display device such as an organic light emitting display device using an organic light emitting diode, a quantum dot light emitting display device including a quantum dot light emitting layer, an inorganic light emitting display device including an inorganic semiconductor, and a micro or nano light emitting display device including a micro or nano light emitting diode (LED), but the disclosure is not limited thereto. For example, the display device 100 may be a type of display device other than the light emitting display device. Hereinafter, embodiments in which the display device 100 is a light emitting display device (e.g., an organic light emitting display device) are disclosed.

The display device 100 may include a display panel 110 including pixels PX, and a first driver 120 and a second driver 130 that supply driving signals to the pixels PX. The display device 100 may further include additional components. For example, the display device 100 may further include a power supply unit for supplying power voltages to the pixels PX, the first driver 120, and the second driver 130, and a timing control unit for controlling operations of the first driver 120 and the second driver 130.

The display panel 110 may include a display area DA and a non-display area NDA. The display area DA may be an area that includes the pixels PX and displays an image. For example, the display area DA may include pixel areas in which each pixel PX is disposed. The non-display area NDA may be an area excluding the display area DA, and an image may not be displayed in the non-display area NDA. In an embodiment, the non-display area NDA may be positioned around the display area DA and surround the display area DA.

In FIGS. 1 and 2, a first direction D1, a second direction D2, and a third direction D3 are defined. In an embodiment, the first direction D1 may be a horizontal direction of the display panel 110, and the second direction D2 may be a vertical direction of the display panel 110. The third direction D3 may be a thickness direction of the display panel 110.

In an embodiment, the display panel 110 may have a rectangular shape in a plan view. FIGS. 1 and 2 schematically illustrate the display panel 110 with a horizontal length greater than a vertical length, but the shape of the display panel 110 is not limited thereto. For example, the display panel 110 may have a shape in which the vertical length is greater than the horizontal length, or may have a square shape, etc. The display panel 110 may include angled corners or rounded corners.

The planar shape of the display panel 110 is not limited to a quadrangular shape illustrated in FIGS. 1 and 2, and the display panel 110 may have other shapes. For example, the display panel 110 may have a non-quadrangular other polygonal shape, a circular shape, an oval shape, an irregular shape, or other shapes in a plan view.

In an embodiment, the display panel 110 may be substantially flat on a plane defined by the first direction D1 and the second direction D2 and may have a uniform thickness in the third direction D3. In another embodiment, the display panel 110 may be provided in a three-dimensional shape having a curved surface, etc.

The display panel 110 may be provided as a rigid panel so as not to be substantially deformed, or may be provided as a flexible panel that may be deformed into a shape such as being foldable, bendable, or rollable at least in a portion. The display panel 110 may be provided to the display device 100 in an unbent state or may be provided to the display device 100 in a bent state in some sections.

The display panel 110 may include a substrate SUB and pixels PX disposed on the substrate SUB. The pixels PX may be disposed in the display area DA on the substrate SUB.

The substrate SUB may be a base member for manufacturing or providing the display panel 110 and may form a base surface of the display panel 110. The substrate SUB may include a display area DA and a non-display area NDA adjacent to the display area DA.

The display area DA may have various shapes depending on embodiments. For example, the display area DA may have a quadrangular shape, a non-quadrangular polygonal shape, a circular shape, an oval shape, an irregular shape, or other shapes in a plan view. In an embodiment, the display area DA may have a shape that matches the shape of the display panel 110.

The pixels PX may be provided and/or arranged in the display area DA. For example, the display area DA may include multiple pixel areas in which each pixel PX is disposed.

In an embodiment, the display device 100 may be a light emitting display device, and each pixel PX may include a light emitting element positioned in each light emitting area and a pixel circuit connected to the light emitting element. In describing embodiments, “connection” may include electrical connection and/or physical connection. Each pixel circuit may include transistors (e.g., transistors, including a driving transistor that generates a driving current corresponding to a data signal, and at least one switching transistor), and at least one capacitor (e.g., a capacitor including a storage capacitor).

The non-display area NDA may include a pad area PA in which pads PD are disposed. In an embodiment, the non-display area NDA may further include a driving circuit area positioned on at least one side of the display area DA. At least one driver, pads PD, and/or lines may be disposed in the non-display area NDA.

At least one driver for driving the pixels PX, or a portion of the driver may be disposed in the driving circuit area. For example, circuit elements constituting the first driver 120 (e.g., driver transistors and driver capacitors constituting stage circuits of the first driver 120) may be disposed in the driving circuit area on the substrate SUB. In an embodiment, the circuit elements of the first driver 120 may be formed in the display panel 110 together with the pixels PX. In an embodiment, the driver transistors provided in the first driver 120 and the transistors provided in the pixels PX may be substantially a same or similar type and/or structure and may be formed simultaneously.

The pads PD may be disposed in the pad area PA. At least one circuit board 140 may be disposed and/or bonded onto the pad area PA. In an embodiment, multiple circuit boards 140 connected to different pads PD may be disposed on the pad area PA. The pads PD may include signal pads and power pads for transmitting driving signals and power voltages for driving the pixels PX and/or the first driver 120 to the inside of the display panel 110.

The first driver 120 and the second driver 130 may generate driving signals for controlling an operation timing and luminance of the pixels PX, and supply the driving signals to the pixels PX. For example, the first driver 120 may be a gate driver including a scan driver, and may be connected to the pixels PX through the respective gate lines. The first driver 120 may supply respective gate signals (e.g., control signals that control driving timing of the pixels PX, including scan signals and/or emission control signal) to the pixels PX. The second driver 130 may be a data driver including source driving circuits, and may be connected to the pixels PX through the respective data lines. The second driver 130 may supply respective data signals to the pixels PX.

In an embodiment, at least one of the first driver 120 and the second driver 130, or a portion of the at least one of the first driver 120 and the second driver 130, may be embedded in the display panel 110. For example, the first driver 120 or a portion of the first driver 120 may be disposed on the substrate SUB of the display panel 110 and may be disposed and/or formed in the non-display area NDA.

It is illustrated in FIG. 1 that the first driver 120 is formed on a side of the display area DA (e.g., the non-display area NDA on the right side of the display area DA), but the disclosure is not limited thereto. For example, the first driver 120 may be positioned only on another side of the display area DA (e.g., the non-display area NDA on the left side of the display area DA), or may be positioned on both sides of the display area DA (e.g., non-display areas NDA on the left and right sides of the display area DA). For example, a portion of the first driver 120 may be positioned in the non-display area NDA, and another portion of the first driver 120 may be positioned in the non-light emitting area (e.g., an area between the light emitting areas of the pixels PX) inside the display area DA.

In an embodiment, another one of the first driver 120 and the second driver 130, or a portion of the another one of the first driver 120 and the second driver 130 may be disposed or formed outside the display panel 110 and may be electrically connected to the display panel 110. For example, the second driver 130 may be implemented with multiple integrated circuit chips and may be disposed on the circuit boards 140 electrically connected to the pixels PX of the display panel 110. The second driver 130 may be implemented with at least one integrated circuit chip and may be mounted on the non-display area NDA of the display panel 110.

The circuit board 140 may be connected to the display panel 110 through pads PD. In an embodiment, the circuit board 140 may be a flexible film such as a flexible printed circuit board (FPCB), a printed circuit board (PCB), or a chip on film (COF), but the disclosure is not limited thereto. In an embodiment, the circuit board 140 may be connected to the timing control unit and/or the power supply unit through another circuit board or a connector.

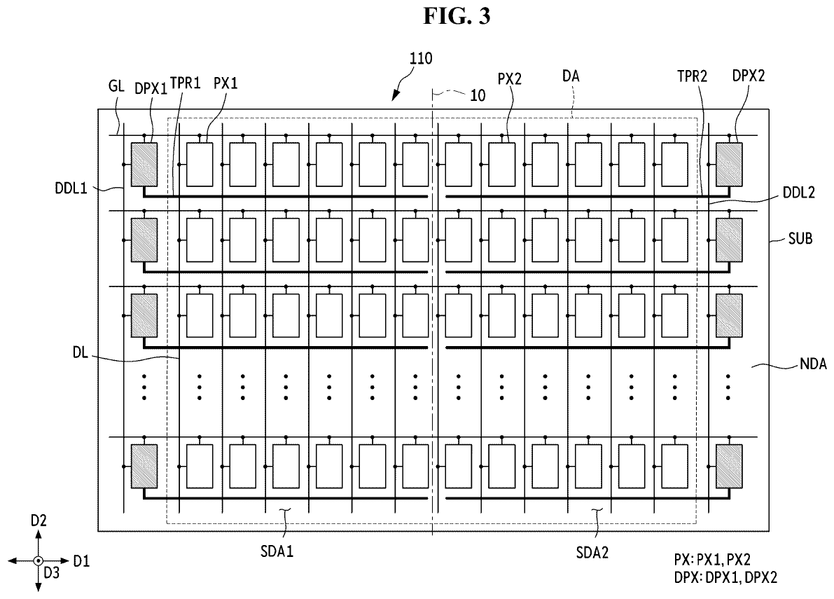

FIG. 3 is a schematic plan view of the display panel 110 of FIG. 1.

As illustrated in FIG. 3, the display panel 110 may include multiple pixels PX and multiple dummy pixels DPX disposed on the substrate SUB.

The pixels PX may be disposed in a matrix form in the display area DA. The pixels PX may be connected to gate lines GL and data lines DL.

Each pixel PX may include light emitting elements.

The pixels PX may include first pixels PX1 and second pixels PX2. For example, in case that a virtual extension line crossing the center of the display area DA along an extension direction of the data line DL (e.g., the second direction D2) is defined as a center line 10, the first pixels PX1 may be disposed between the center line 10 and an edge of the display area DA, and the second pixels PX2 may be disposed between the center line 10 and another edge of the display area DA. In other words, since the center line 10 is disposed between first repair lines TPR1 and second repair lines TPR2 to divide the display area DA into a first sub-display area SDA1 and a second sub-display area SDA2, the first pixels PX1 may be disposed in the first sub-display area SDA1, and the second pixels PX2 may be disposed in the second sub-display area SDA2.

The dummy pixels DPX may be disposed in the non-display area NDA. The dummy pixels DPX may be used, for example, to repair defective pixels. Each of the dummy pixels DPX may include a dummy pixel circuit. Each of the dummy pixels DPX may not include the light emitting element.

The dummy pixels DPX may include first dummy pixels DPX1 for repairing the first pixels PX1 and second dummy pixels DPX2 for repairing the second pixels PX2. The first dummy pixels DPX1 may be disposed adjacent to the first pixels PX1 adjacent to an edge of the display area DA, and the second dummy pixels DPX2 may be disposed adjacent to the second pixels PX2 adjacent to another edge of the display area DA.

The first dummy pixels DPX1 may be connected to the gate lines GL, a first dummy data line DDL1, and the first repair lines TPR1. For example, a first dummy pixel DPX1 may be connected to one of the gate lines GL, may be commonly connected to the first dummy data line DDL1, and may be connected to one of the first repair lines TPR1.

The second dummy pixels DPX2 may be connected to the gate lines GL, a second dummy data line DDL2, and the second repair lines TPR2. For example, a second dummy pixel DPX2 may be connected to one of the gate lines GL, may be commonly connected to the second dummy data line DDL2, and may be connected to one of the second repair lines TPR2.

The first dummy data line DDL1 and the second dummy data line DDL2 may be each connected to the second driver 130. The first dummy data line DDL1 may receive a first dummy data signal from the second driver 130, and the second dummy data line DDL2 may receive a second dummy data signal from the second driver 130.

The first repair lines TPR1 may be disposed in the first sub-display area SDA1. The first repair lines TPR1 may be respectively extended to the non-display area NDA in which the first dummy pixels DPX1 are disposed and connected to the first dummy pixels DPX1. For example, a side of each of the first repair lines TPR1 may be connected to each of the first dummy pixels DPX1 in the non-display area NDA. Each of the first repair lines TPR1 may extend in a direction (e.g., the first direction D1) perpendicular to an extension direction of the data line DL (e.g., the second direction D2) in the first sub-display area SDA1. The first repair lines TPR1 may be arranged in the extension direction of the data line DL (e.g., the second direction D2) in the first sub-display area SDA1.

The second repair lines TPR2 may be disposed in the second sub-display area SDA2. The second repair lines TPR2 may be respectively extended to the non-display area NDA in which the second dummy pixels DPX2 are disposed and connected to the second dummy pixels DPX2. For example, a side of each of the second repair lines TPR2 may be connected to each of the second dummy pixels DPX2 in the non-display area NDA. Each of the second repair lines TPR2 may extend in a direction (e.g., the first direction D1) perpendicular to the extension direction of the data line DL (e.g., the second direction D2) in the second sub-display area SDA2. The second repair lines TPR2 may be arranged in the extension direction of the data line DL (e.g., the second direction D2) in the second sub-display area SDA2.

Another side of each of the first repair lines TPR1 may face the other side of each of the second repair lines TPR2 in the display area DA. The above-described virtual center line 10 may be disposed between the another side of each of the first repair lines TPR1 and another side of each of the second repair lines TPR2.

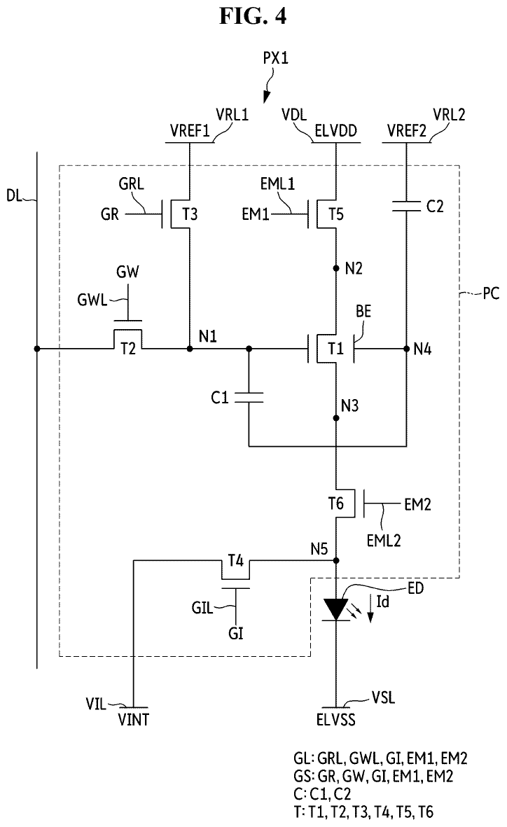

FIG. 4 is a schematic diagram of an equivalent circuit of a first pixel PX1 according to an embodiment. For example, FIG. 4 may be a schematic diagram illustrating an equivalent circuit of the first pixel PX1 of FIG. 3. In addition to the embodiment of FIG. 4, the type and/or structure of the first pixel PX1 that may be included in the display device 100 may be variously changed depending on embodiments.

Referring to FIG. 4 in addition to FIGS. 1 and 3, the first pixel PX1 may include a light emitting element ED and a pixel circuit PC connected to the light emitting element ED. The light emitting element ED may be a light source of the first pixel PX1 and may be, for example, an organic light emitting diode, but the disclosure is not limited thereto. The pixel circuit PC may control the light emitting timing and luminance of the light emitting element ED.

The pixel circuit PC may include transistors T and at least one capacitor C. For example, the pixel circuit PC may include first to sixth transistors T1 to T6, a first capacitor C1, and a second capacitor C2. FIG. 4 schematically illustrates an embodiment in which all transistors T1 to T6 are N-type transistors, but the type of transistors T is not limited thereto. For example, at least one transistor T may be formed of a P-type transistor.

The pixel circuit PC may supply a driving current Id to the light emitting element ED in response to the driving signals supplied from the first driver 120 and the second driver 130. For example, the pixel circuit PC may supply the driving current Id to the light emitting element ED in response to each gate signal GS supplied from the first driver 120 through each gate line GL, and the data signal supplied from the second driver 130 through the data line DL.

The first transistor T1 may be a driving transistor of the first pixel PX1, and a drain-source current (e.g., the driving current Id) of the first transistor T1 may be determined depending on a gate-source voltage. The second, third, fourth, fifth, and sixth transistors T2, T3, T4, T5, and T6 may be switching transistors that are turned on or off depending on the respective gate-source voltages. Depending on the type (e.g., P-type or N-type transistor) and/or operating condition of each of the first to sixth transistors T1 to T6, a first electrode of each of the first to sixth transistors T1 to T6 may be a drain electrode (or a drain region) or a source electrode (or source region), and a second electrode of each of the first to sixth transistors T1 to T6 may be an electrode different from the first electrode. For example, in case that the first electrode is a drain electrode, the second electrode may be a source electrode.

The first pixel PX1 may be connected to a first gate line GWL transmitting a first gate signal GW (e.g., a scan signal), a second gate line GIL transmitting a second gate signal GI, a third gate line GRL transmitting a third gate signal GR, a first emission control line EML1 transmitting a first emission control signal EM1, a second emission control line EML2 transmitting a second emission control signal EM2, and a data line DL transmitting a data signal. The first pixel PX1 may be connected to a first driving power line VDL that transmits a first pixel PX1 voltage ELVDD (also referred to as “first pixel PX1 power voltage”), and a second driving power line VSL that transmits a second pixel PX2 voltage ELVSS (also referred to as “second pixel PX2 power voltage”). In an embodiment, the first pixel PX1 may be further connected to an initialization power line VIL transmitting an initialization voltage VINT (also referred to as “third pixel power voltage”), a first reference power line VRL1 transmitting a first reference voltage VREF1 (also referred to as “fourth pixel power voltage”), and a second reference power line VRL2 transmitting a second reference voltage VREF2 (also referred to as “fifth pixel power voltage”).

In an embodiment, the first to sixth transistors T1 to T6 may be oxide transistors (also referred to as “oxide semiconductor transistors”) including an oxide semiconductor (e.g., an oxide semiconductor material). For example, an active layer of each of the first to sixth transistors T1 to T6 may include an oxide semiconductor. However, the disclosure is not limited thereto. For example, at least one transistor T may also be formed of another semiconductor material (e.g., amorphous silicon or polysilicon) other than the oxide semiconductor.

The oxide semiconductor may have high carrier mobility and low leakage current, and accordingly, even if a driving time of the oxide transistor becomes longer, a voltage drop may not significantly occur. For example, the first pixel PX1 including the oxide transistor may be driven at a low frequency because the luminance and/or color of an image does not significantly change due to the voltage drop even driven at the low frequency. In case that the first to sixth transistors T1 to T6 are formed as the oxide transistors, leakage current of the first pixel PX1 may be reduced or prevented and power consumption may be reduced.

Since the oxide semiconductor is sensitive to light, the amount of current, etc. may vary due to external light. In an embodiment, the external light may be blocked by forming a light blocking pattern or a light blocking electrode (e.g., a bottom electrode or a back-gate electrode) on a lower portion of the active layer included in at least one transistor T. Accordingly, operating characteristics of the transistor T may be stabilized.

The first transistor T1 may include a gate electrode connected to a first node N1, a first electrode (e.g., a first drain electrode) connected to a second node N2, and a second electrode (e.g., a first source electrode) connected to a third node N3. The first electrode of the first transistor T1 may be connected to the first driving power line VDL via the fifth transistor T5, and the second electrode of the first transistor T1 may be connected to the light emitting element ED via the sixth transistor T6. The first transistor T1 may control the size (e.g., amount of current) of the driving current Id flowing to the light emitting element ED in response to the data signal transmitted from the first node N1.

In an embodiment, the first transistor T1 may further include a bottom electrode BE (e.g., a bottom-gate electrode or a back-gate electrode of the first transistor T1) connected to a fourth node N4. In case that the bottom electrode BE of the first transistor T1 is connected to the fourth node N4 to form the first transistor T1 as a transistor with a double gate structure (e.g., a double gate transistor with a source-sync structure), the operating characteristics of the first transistor T1 may be improved.

The second transistor T2 may include a second gate electrode connected to the first gate line GWL, a first electrode (e.g., a second drain electrode) connected to the data line DL, and a second electrode (e.g., a second source electrode) connected to the first node N1. The second transistor T2 may be turned on by the first gate signal GW (e.g., the first gate signal GW of a gate-on voltage) transmitted to the first gate line GWL and connect the data line DL and the first node N1 to each other. Accordingly, the data signal transmitted to the data line DL may be transmitted to the first node N1.

The third transistor T3 may include a gate electrode connected to the third gate line GRL, a first electrode (e.g., a third source electrode) connected to the first reference power line VRL1, and a second electrode (e.g., a third drain electrode) connected to the first node N1. The third transistor T3 may be turned on by the third gate signal GR transmitted to the third gate line GRL and transmit the first reference voltage VREF1 transmitted from the first reference power line VRL1 to the first node N1.

The fourth transistor T4 may include a gate electrode connected to the second gate line GIL, a first electrode (e.g., a fourth drain electrode) connected to a fifth node N5, and a second electrode (e.g., a fourth source electrode) connected to the initialization power line VIL. The fourth transistor T4 may be turned on by the second gate signal GI transmitted to the second gate line GIL and transmit the initialization voltage VINT transmitted from the initialization power line VIL to the fifth node N5.

The fifth transistor T5 may include a gate electrode connected to the first emission control line EML1, a first electrode (e.g., a fifth drain electrode) connected to the first driving power line VDL, and a second electrode (e.g., a fifth source electrode) connected to the second node N2 (or the first electrode of the first transistor T1). The fifth transistor T5 may be turned on by a first emission control signal EM1 (e.g., a first emission control signal EM1 of a gate-on voltage) transmitted from the first emission control line EML1 and control a light emitting timing of the first pixel PX1.

The sixth transistor T6 may include a gate electrode connected to the second emission control line EML2, a first electrode (e.g., a sixth drain electrode) connected to the third node N3 (or the second electrode of the first transistor T1), and a second electrode (e.g., a fifth source electrode) connected to the fifth node N5. The sixth transistor T6 may be turned on by a second emission control signal EM2 (e.g., a second emission control signal EM2 of a gate-on voltage) transmitted from the second emission control line EML2 and control a light emitting timing of the first pixel PX1.

Each of the second to sixth transistors T2 to T6 may or may not include a bottom electrode. In an embodiment, at least one switching transistor of the second to sixth transistors T2 to T6 may include a bottom electrode, and the bottom electrode of the at least one switching transistor may be connected to the gate electrode of the corresponding switching transistor. In case that the bottom electrode of the switching transistor is connected to the gate electrode, the off-characteristics and switching speed of the switching transistor may be improved, an additional voltage tolerance range may be secured, leakage current may be reduced, and voltage stability may be improved. For example, by forming a switching transistor formed as an oxide transistor with a short channel length in the double gate structure such as a gate-sink structure, the operating characteristics of the switching transistor may be improved.

The first capacitor C1 may be connected between the first node N1 and the fourth node N4. The first capacitor C1, which is a storage capacitor of the first pixel PX1, may store a voltage corresponding to a threshold voltage and a data signal of the first transistor T1.

The second capacitor C2 may be connected between the second reference power line VRL2 and the fourth node N4 (e.g., the bottom electrode BE of the first transistor T1). In an embodiment, the capacitance of the second capacitor C2 may be smaller than the capacitance of the first capacitor C1.

The light emitting element ED may be connected between the fifth node N5 and the second driving power line VSL. For example, the light emitting element ED may include a first electrode (e.g., an anode electrode or a pixel electrode) connected to the fifth node N5, a second electrode (e.g., a cathode electrode or a counter electrode) facing the first electrode and connected to the second driving power line VSL, and a light emitting layer interposed between the first electrode and the second electrode. In an embodiment, the first electrode of the light emitting element ED may be an individual electrode (e.g., an anode electrode) provided individually to each pixel PX, and the second electrode of the light emitting element ED may be a common electrode (e.g., a cathode electrode) shared by multiple pixels PX. The light emitting element ED may emit light with a luminance corresponding to the driving current Id supplied from the pixel circuit PC.

According to an embodiment, each of the second pixels PX2 may have the same circuit configuration as the first pixel PX1 of FIG. 4 described above. For example, each of the second pixels PX2 may include a pixel circuit PC and a light emitting element ED substantially similar to the embodiment of FIG. 4.

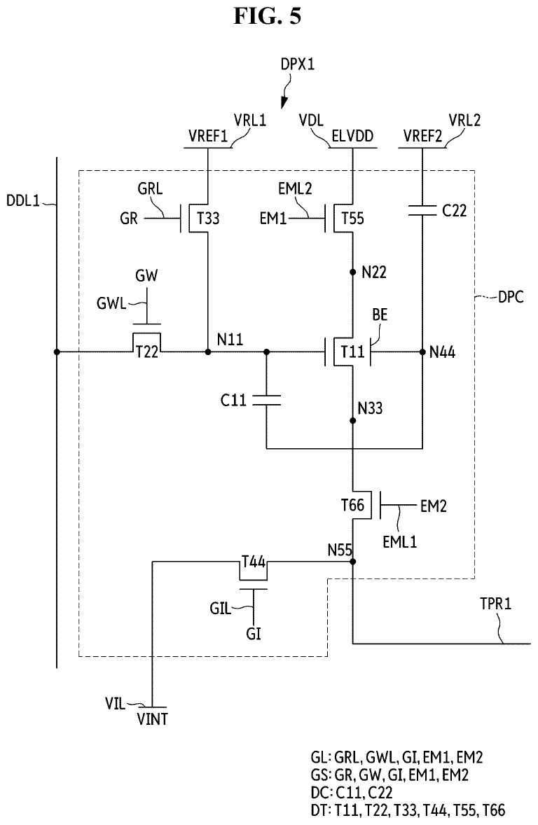

FIG. 5 is a schematic diagram of an equivalent circuit of a first dummy pixel DPX1 according to an embodiment. For example, FIG. 5 may be a schematic diagram illustrating an equivalent circuit of the first dummy pixel DPX1 of FIG. 3. In addition to the embodiment of FIG. 5, the type and/or structure of the first dummy pixel DPX1 that may be included in the display device 100 may be variously changed depending on embodiments.

Referring to FIG. 5 in addition to FIGS. 1 to 3, the first dummy pixel DPX1 may include a dummy pixel circuit DPC. The dummy pixel circuit DPC and the pixel circuit PC of the pixel (e.g., the first pixel PX1) may have a same configuration.

The dummy pixel circuit DPC may include dummy transistors DT and at least one dummy capacitor DC. For example, the dummy pixel circuit DPC may include first to sixth dummy transistors T11 to T66, a first dummy capacitor C11, and a second dummy capacitor C22.

Since a first dummy transistor T11, a second dummy transistor T22, a third dummy transistor T33, a fourth dummy transistor T44, a fifth dummy transistor T55, a sixth dummy transistor T66, a first dummy capacitor C11, a second dummy capacitor C22, a first dummy node N11, a second dummy node N22, a third dummy node N33, a fourth dummy node N44, and a fifth dummy node N55 may be same as the first transistor T1, the second transistor T2, the third transistor T3, the fourth transistor T4, the fifth transistor T5, the sixth transistor T6, the first capacitor C1, the second capacitor C2, the first node N1, the second node N2, the third node N3, the fourth node N4, and the fifth node N5 of FIG. 4 described above, respectively, the description of the first to sixth dummy transistors T11 to T66, the first and second dummy capacitors C11 and C22, and the first to fifth dummy nodes N11 to N55 of FIG. 5 may be same as the description of the first to sixth transistors T1 to T6, the first and second capacitors C1 and C2, and the first to fifth nodes N1 to N5 of FIG. 4.

According to an embodiment, the fifth dummy node N55 of the first dummy pixel DPX1 may be connected to the first repair line TPR1. For example, a drain electrode of the fourth dummy transistor T44 provided in the first dummy pixel DPX1 and a source electrode of the sixth dummy transistor T66 provided in the first dummy pixel DPX1 may each be connected to the first repair line TPR1.

According to an embodiment, the second dummy pixel DPX2 and the first dummy pixel DPX1 may have a same circuit configuration. However, the fifth dummy node of the second dummy pixel DPX2 may be connected to the second repair line TPR2. For example, a drain electrode of the fourth dummy transistor provided in the second dummy pixel DPX2 and a source electrode of the sixth dummy transistor provided in the second dummy pixel DPX2 may each be connected to the second repair line TPR2.

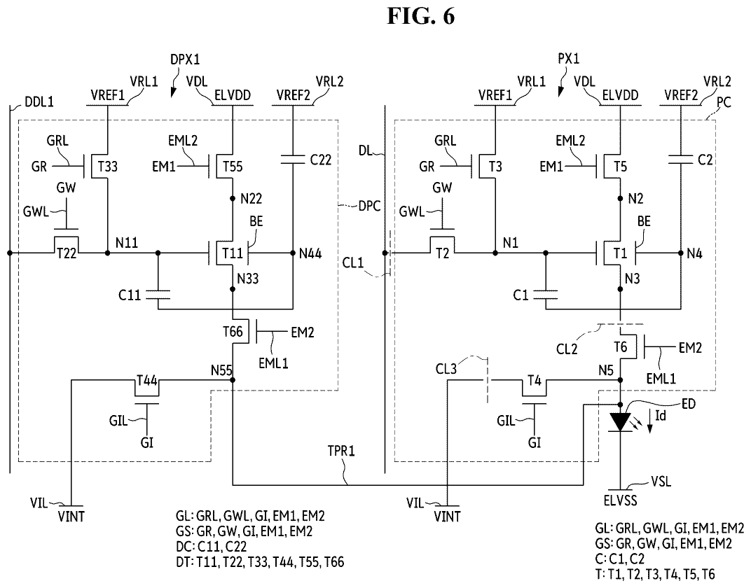

FIG. 6 is a schematic diagram of an equivalent circuit for describing a method for repairing a defective pixel according to an embodiment.

In case that an abnormality occurs in the pixel circuit PC of the first pixel PX1 and one of the transistors of the pixel circuit PC does not normally operate, the light emitting element ED of the first pixel PX1 may not emit light, or may provide light having luminance different from a grayscale of the data signal provided to the first pixel PX1.

In case that the first pixel PX1 is determined to be a defective pixel, the pixel circuit PC of the first pixel PX1 may first be separated from the data line DL and the light emitting element ED, in order to repair the first pixel PX1. For example, the second transistor T2 and the data line DL may be separated from each other, the first transistor T1 and the sixth transistor T6 may be separated from each other, and the fourth transistor T4 and the initialization power line VIL may be separated from each other. To this end, according to an embodiment, the drain electrode of the second transistor T2 may be cut along a first cut line CL1, the drain electrode of the sixth transistor T6 may be cut along a second cut line CL2, and the initialization power line VIL may be cut along a third cut line CL3. By such a cutting process, the light emitting element ED of the first pixel PX1, which is a defective pixel, may be physically and electrically separated from the pixel circuit PC of the first pixel PX1. Such a cutting process may be performed, for example, by irradiating a laser beam to the corresponding electrode or line along each cut line CL1 to CL3.

The first repair line TPR1 connected to the first dummy pixel DPX1 and the light emitting element ED of the first pixel PX1 may be connected to each other. For example, the first repair line TPR1 and the anode electrode of the light emitting element ED may be connected to each other. Accordingly, the fifth dummy node N55 of the first dummy pixel DPX1 may be connected to the anode electrode of the light emitting element ED through the first repair line TPR1. Such a connecting process may be performed, for example, by irradiating a laser beam onto an overlapping area of the first repair line TPR1 and the corresponding connection electrode.

Thereafter, the first dummy data signal from the second driver 130 may be provided to the first dummy data line DDL1. The first dummy data signal may be, for example, identical to the data signal provided to the data line DL separated from the first pixel PX1. A value of the first dummy data signal may be determined depending on the position of the first pixel PX1 determined to be a defective pixel.

According to the cutting process of the first pixel PX1 and the connecting process between the first pixel PX1 and the first dummy pixel DPX1, the light emitting element ED of the first pixel PX1 may receive a driving current provided from the dummy pixel circuit DPC of the first dummy pixel DPX1 instead of the pixel circuit PC of the first pixel PX1. In other words, the first dummy pixel DPX1 may supply the driving current to the light emitting element ED in response to the first dummy data signal supplied from the second driver 130 through the first dummy data line DDL1. Therefore, the light emitting element of the first pixel PX1, which is a defective pixel, may normally emit light.

According to an embodiment, a repair process for the second pixel PX2 determined to be a defective pixel and the repair process for the first pixel PX1 described above may be performed in a same manner except that, during the repair process of the second pixel PX2, the light emitting element of the second pixel PX2 may be connected to the second repair line TPR2. In other words, the anode electrode of the light emitting element provided in the second pixel PX2 may be connected to the second dummy pixel DPX2 through the second repair line TPR2.

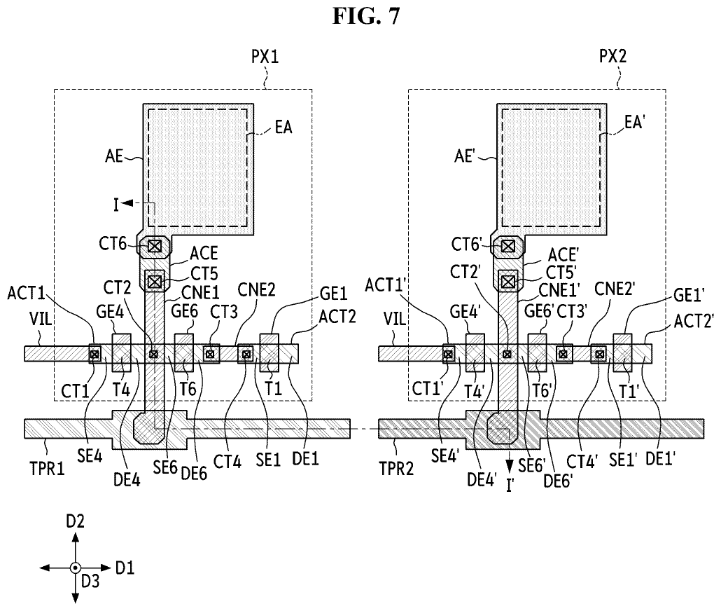

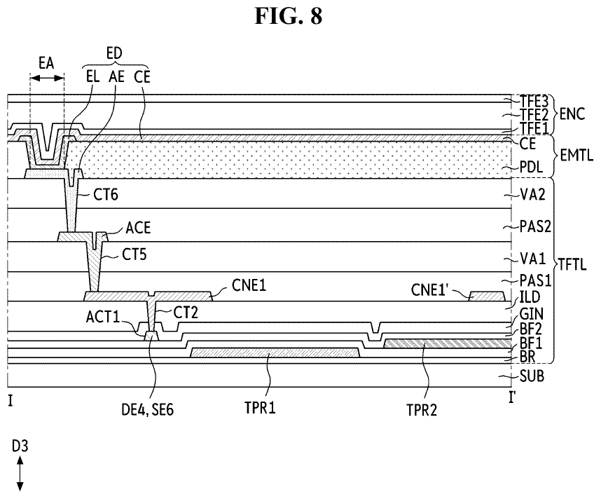

According to an embodiment, the first repair line TPR1 and the second repair line TPR2 may be disposed on different layers. For example, based on the thickness direction (e.g., the third direction D3) of the display panel 110, the first repair line TPR1 and the second repair line TPR2 may be disposed at different heights. This will be specifically described with reference to FIGS. 7 and 8 as follows.

FIG. 7 is a schematic diagram illustrating a planar array of the display device 100 according to an embodiment and FIG. 8 is a schematic cross-sectional view taken along line I-I′ of FIG. 7.

FIG. 7 schematically illustrates an array of a first pixel PX1, a second pixel PX2, a first repair line TPR1, and a second repair line TPR2.

The first pixel PX1 may include an anode electrode AE and a light emitting area EA.

The second pixel PX2 may include an anode electrode AE′ and a light emitting area EA′.

FIG. 7 schematically illustrates a first transistor T1, a fourth transistor T4, and a sixth transistor T6 among the first to sixth transistors T1 to T6 of the first pixel PX1, and a first transistor T1′, a fourth transistor T4′, and a sixth transistor T6′ among the first to sixth transistors of the second pixel PX2.

The first transistor T1 of the first pixel PX1 may include a source electrode SE1 and a drain electrode DEI defined in a second active layer ACT2. The first transistor T1 of the first pixel PX1 may further include a gate electrode GE1 overlapping the second active layer ACT2 in a plan view between the source electrode SE1 and the drain electrode DE1.

The fourth transistor T4 of the first pixel PX1 may include a source electrode SE4 and a drain electrode DE4 defined in a first active layer ACT1. The fourth transistor T4 of the first pixel PX1 may further include a gate electrode GE4 overlapping the first active layer ACT1 in a plan view between the source electrode SE4 and the drain electrode DE4.

The sixth transistor T6 of the first pixel PX1 may include a source electrode SE6 and a drain electrode DE6 defined in the first active layer ACT1. The sixth transistor T6 of the first pixel PX1 may further include a gate electrode GE6 overlapping the first active layer ACT1 in a plan view between the source electrode SE6 and the drain electrode DE6.

The source electrode SE1 of the first transistor T1 of the first pixel PX1 may be connected to the drain electrode DE6 of the sixth transistor T6 through a second connection electrode CNE2. A side of the second connection electrode CNE2 may be connected to the source electrode SE1 of the first transistor T1 through a fourth contact hole CT4 of an insulating layer, and another side of the second connection electrode CNE2 may be connected to the drain electrode DE6 of the sixth transistor T6 through a third contact hole CT3.

The source electrode SE4 of the fourth transistor T4 of the first pixel PX1 may be connected to the initialization power line VIL. The initialization power line VIL may be connected to the source electrode SE4 of the fourth transistor T4 through a first contact hole CTI of the insulating layer.

The drain electrode DE4 of the fourth transistor T4 of the first pixel PX1 may be connected to a first connection electrode CNE1. The first connection electrode CNE1 may be connected to the drain electrode DE4 of the fourth transistor T4 through a second contact hole CT2 of the insulating layer.

The source electrode SE6 of the sixth transistor T6 of the first pixel PX1 may be connected to the first connection electrode CNE1. The first connection electrode CNE1 may be connected to the source electrode SE6 of the sixth transistor T6 through the second contact hole CT2 of the insulating layer.

An anode connection electrode ACE of the first pixel PX1 may connect the first connection electrode CNE1 and the anode electrode AE to each other. A side of the anode connection electrode ACE may be connected to the first connection electrode CNE1 through a fifth contact hole CT5 of the insulating layer, and another side of the anode connection electrode ACE may be connected to the anode electrode AE through a sixth contact hole CT6.

A side of the first connection electrode CNE1 of the first pixel PX1 may extend toward the first repair line TPR1 and overlap the first repair line TPR1 in a plan view.

The first transistor T1′ of the second pixel PX2 may include a source electrode SE1′ and a drain electrode DE1′ defined in a second active layer ACT2′. The first transistor T1′ of the second pixel PX2 may further include a gate electrode GE1′ overlapping the second active layer ACT2′ in a plan view between the source electrode SE1′ and the drain electrode DE1′.

The fourth transistor T4′ of the second pixel PX2 may include a source electrode SE4′ and a drain electrode DE4′ defined in a first active layer ACT1′. The fourth transistor T4′ of the second pixel PX2 may further include a gate electrode GE4′ overlapping the first active layer ACT1′ in a plan view between the source electrode SE4′ and the drain electrode DE4′.

The sixth transistor T6′ of the second pixel PX2 may include a source electrode SE6′ and a drain electrode DE6′ defined in the first active layer ACT1′. The sixth transistor T6′ of the second pixel PX2 may further include a gate electrode GE6′ overlapping the first active layer ACT1′ in a plan view between the source electrode SE6′ and the drain electrode DE6′.

The source electrode SE1′ of the first transistor T1′ of the second pixel PX2 may be connected to the drain electrode DE6′ of the sixth transistor T6′ through a second connection electrode CNE2′. A side of the second connection electrode CNE2′ may be connected to the source electrode SE1′ of the first transistor T1′ through a fourth contact hole CT4′ of an insulating layer, and another side of the second connection electrode CNE2′ may be connected to the drain electrode DE6′ of the sixth transistor T6′ through a third contact hole CT3′.

The source electrode SE4′ of the fourth transistor T4′ of the second pixel PX2 may be connected to the initialization power line VIL. The initialization power line VIL may be connected to the source electrode SE4′ of the fourth transistor T4′ through a first contact hole CT1′ of the insulating layer.

The drain electrode DE4′ of the fourth transistor T4′ of the second pixel PX2 may be connected to a first connection electrode CNE1′. The first connection electrode CNE1′ may be connected to the drain electrode DE4′ of the fourth transistor T4′ through a second contact hole CT2′ of the insulating layer.

The source electrode SE6′ of the sixth transistor T6′ of the second pixel PX2 may be connected to the first connection electrode CNE1′. The first connection electrode CNE1′ may be connected to the source electrode SE6′ of the sixth transistor T6′ through the second contact hole CT2′ of the insulating layer.

An anode connection electrode ACE′ of the second pixel PX2 may connect the first connection electrode CNE1′ and the anode electrode AE′ to each other. A side of the anode connection electrode ACE′ may be connected to the first connection electrode CNE1′ through a fifth contact hole CT5′ of the insulating layer, and another side of the anode connection electrode ACE′ may be connected to the anode electrode AE′ through a sixth contact hole CT6′.

A side of the first connection electrode CNE1′ of the second pixel PX2 may extend toward the second repair line TPR2 and overlap the second repair line TPR2 in a plan view.

As illustrated in FIG. 8, the display device 100 may include a substrate SUB, a thin film transistor layer TFTL, a light emitting element layer EMTL, and an encapsulation layer ENC. The thin film transistor layer TFTL, the light emitting element layer EMTL, and the encapsulation layer ENC may be sequentially disposed on the substrate SUB in the third direction D3. The thin film transistor layer TFTL may include the first transistors T1 and T1′, the second transistors T2 and T2′, the third transistors T3 and T3′, the fourth transistors T4 and T4′, the fifth transistors T5 and T5′, the sixth transistors T6 and T6′, the first capacitor C1, and the second capacitor C2 described above.

The substrate SUB may be a rigid substrate SUB or be a flexible substrate SUB that may be bent, folded, rolled, or the like. The substrate SUB may be made of an insulating material such as glass, quartz, or a polymer resin. Examples of the polymer material in a polymer resin may include polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP), or a combination thereof. In another embodiment, the substrate SUB may include a metal material.

A barrier layer BR may be disposed on the substrate SUB. For example, the barrier layer BR may be disposed on an entire surface of the substrate SUB. The barrier layer BR may be a film for protecting the transistors T1 to T6 of the thin film transistor layer TFTL and the light emitting layer EL of the light emitting element layer EMTL from moisture permeating through the substrate SUB that is vulnerable to moisture permeation. The barrier layer BR may include multiple inorganic films alternately stacked each other. For example, the barrier layer BR may be formed of a multi-film in which one or more inorganic films of a silicon nitride layer, a silicon oxynitride layer, a silicon oxide layer, a titanium oxide layer, and an aluminum oxide layer are alternately stacked each other.

A first repair line TPR1 may be disposed on the barrier layer BR. The first repair line TPR1 may be made of a metal.

A first buffer layer BF1 may be disposed on the first repair line TPR1. The first buffer layer BF1 may be a film for protecting the transistors T1 to T6 and T1′ to T6′ of the thin film transistor layer TFTL and the light emitting layer EL of the light emitting element layer EMTL from moisture permeating through the substrate SUB that is vulnerable to moisture permeation. The first buffer layer BF1 may include multiple inorganic films alternately stacked each other. For example, the first buffer layer BF1 may be formed of a multi-film in which one or more inorganic films of a silicon nitride layer, a silicon oxynitride layer, a silicon oxide layer, a titanium oxide layer, and an aluminum oxide layer are alternately stacked each other.

A second repair line TPR2 may be disposed on the first buffer layer BF1. The second repair line TPR2 may be made of a metal. The second repair line TPR2 and the first repair line TPR1 may be disposed on different layers. Therefore, in cross-sectional view as illustrated in FIG. 8, an end portion (e.g., the other side) of the first repair line TPR1 and an end portion (e.g., the other side) of the second repair line TPR2 may not face each other.

Since the first repair line TPR1 and the second repair line TPR2 are each in a floating state before repairing the first pixel PX1 and the second pixel PX2, a high-magnitude electric field (or electric field) may be formed around the end portion of the first repair line TPR1 and the end portion of the second repair line TPR2. Therefore, in case that the first repair line TPR1 and the second repair line TPR2 are disposed on a same layer so that the end portion of the first repair line TPR1 and the end portion of the second repair line TPR2 face each other, static electricity may be generated between the end portion of the first repair line TPR1 and the end portion of the second repair line TPR2. For example, static electricity may be generated between an end portion of the first repair line TPR1 and an end portion of the second repair line TPR2 by triboelectrification during the transport of the substrate SUB including the first repair line TPR1 and the second repair line TPR2 disposed on a same layer. The first repair line TPR1 and the second repair line TPR2 may be damaged by such static electricity.

According to an embodiment, since the first repair line TPR1 and the second repair line TPR2 are disposed on different layers so that an end portion of the first repair line TPR1 and an end portion of the second repair line TPR2 do not face each other in a cross-sectional view as described above, the generation of static electricity between the end portion of the first repair line TPR1 and the end portion of the second repair line TPR2 may be prevented (or minimized).

According to an embodiment, the first repair line TPR1 may be disposed closer to the substrate SUB than the second repair line TPR2. For example, a distance between an upper surface of the substrate SUB (e.g., an interface between the substrate SUB and the barrier layer BR) and the second repair line TPR2 in the third direction D3 may be greater than a distance between the upper surface of the substrate SUB and the first repair line TPR1.

According to an embodiment, the number of insulating layers between the substrate SUB and the second repair line TPR2 may be greater than the number of insulating layers between the substrate SUB and the first repair line TPR1. For example, one insulating layer (e.g., the barrier layer BR) may be disposed between the substrate SUB and the first repair line TPR1, and two insulating layers (e.g., the barrier layer BR and the first buffer layer BF1) may be disposed between the substrate SUB and the second repair line TPR2.

According to an embodiment, in a plan view and in a cross-sectional view, the first repair line TPR1 and the second repair line TPR2 may not overlap. For example, since the first buffer layer BF1 may be disposed between the first repair line TPR1 and the second repair line TPR2, the second repair line TPR2 may be disposed on the first buffer layer BF1 so as not to overlap the first repair line TPR1.

According to an embodiment, since the second repair line TPR2 is formed after the process of forming the first repair line TPR1, damage to the first repair line TPR1 may be prevented even if the static electricity is generated due to friction during the transport of the substrate SUB on which the first repair line TPR1 is disposed. This is because only the first repair line TPR1 is formed on the substrate SUB being transported.

According to an embodiment, since the second repair line TPR2 may be formed together with other signal lines or power lines, the second repair line TPR2 may be formed without a separate additional process.

A second buffer layer BF2 may be disposed on the second repair line TPR2. The second buffer layer BF2 and the first buffer layer BF1 described above may include a same material.

The active layers forming each of the drain electrodes DE1, DE1′, DE4, DE4′, DE6, and DE6′ and each of the source electrodes SE1, SE1′, SE4, SE4′, SE6, and SE6′ of each of the transistors T1 to T6 and T1′ to T6′ may be disposed on the second buffer layer BF2. For example, first active layers ACT1 and ACT1′ and second active layers ACT2 and ACT2′ may be disposed on the second buffer layer BF2. The first active layers ACT1 and ACT1′ may be oxide-based active layers. For example, the first active layers ACT1 and ACT1′ may include a semiconductor such as indium-gallium-zinc-oxide (IGZO) or indium-gallium-zinc-tin oxide (IGZTO). The second active layers ACT2 and ACT2′ and the first active layer ACT1 and ACT1′ may include a same material. For example, the second active layers ACT2 and ACT2′ may be oxide-based active layers.

A gate insulating layer GIN may be disposed on the first active layers ACT1 and ACT1′ and the second active layers ACT2 and ACT2′. The gate insulating layer GIN may include at least one of tetraethoxysilane (TetraEthylOrthoSilicate, TEOS), silicon nitride (SiNₓ), and silicon oxide (SiO₂). For example, the gate insulating layer GIN may have a double film structure in which a silicon nitride film having a thickness of about 40 nm and a tetraethoxysilane film having a thickness of about 80 nm are sequentially stacked.

On the gate insulating layer GIN, each of the gate electrodes GE1, GE4, GE6, GE1′, GE4′, and GE6′ of each of the transistors T1 to T6 and T1′ to T6′ and the gate line GL may be disposed. For example, on the gate insulating layer, the gate electrodes GE1 and GE1′ of the first transistors T1 and T1′, the gate electrodes GE4 and GE4′ of the fourth transistors T4 and T4′, and the gate electrodes GE6 and GE6′ of the sixth transistors T6 and T6′ may be disposed. The gate electrodes GE1 and GE1′ of the first transistors T1 and T1′ may be disposed on the gate insulating layer GIN so as to overlap the channel regions of the first transistors T1 and T1′ of the second active layers ACT2 and ACT2′, the gate electrodes GE4 and GE4′ of the fourth transistors T4 and T4′ may be disposed on the gate insulating layer GIN so as to overlap the channel regions of the fourth transistors T4 and T4′ of the first active layers ACT1 and ACT1′, and the gate electrodes GE6 and GE6′ of the sixth transistors T6 and T6′ may be disposed on the gate insulating layer GIN so as to overlap the channel regions of the sixth transistors T6 and T6′ of the first active layers ACT1 and ACT′ in a plan view.

An interlayer insulating layer ILD may be disposed on the gate electrodes GE1, GE1′, GE4, GE4′, GE6, and GE6′ and the gate line GL. The interlayer insulating layer ILD may include an inorganic film, for example, a silicon nitride layer, a silicon oxynitride layer, a silicon oxide layer, a titanium oxide layer, or an aluminum oxide layer. In an embodiment, the interlayer insulating layer ILD may include multiple inorganic films.

Various signal lines, various power lines, and various connection electrodes may be disposed on the interlayer insulating layer ILD. For example, on the interlayer insulating layer ILD, the data line DL, the first dummy data line DDL1, the second dummy data line DDL2, the initialization power line VIL, the first connection electrodes CNE1 and CNE1′, and the second connection electrodes CNE2 and CNE2′ may be disposed.

The first connection electrodes CNE1 and CNE1′ may be connected to the drain electrodes DE4 and DE4′ of the fourth transistors T4 and T4′ or the source electrodes SE6 and SE6′ of the sixth transistor T6 and T6′ through the second contact holes CT2 and CT2′ penetrating through the interlayer insulating layer ILD and the gate insulating layer GIN. The first connection electrodes CNE1 and CNE1′ may overlap the repair line in a plan view. For example, the first connection electrode CNE1 of the first pixel PX1 may overlap the first repair line TPR1, and the first connection electrode CNE1′ of the second pixel PX2 may overlap the second repair line TPR2 in a plan view.

A side of the second connection electrodes CNE2 and CNE2′ may be connected to the source electrodes SE1 and SE1′ of the first transistors T1 and T1′ through the fourth contact holes CT4 and CT4′ penetrating through the interlayer insulating layer ILD and the gate insulating layer GIN. Another other side of the second connection electrodes CNE2 and CNE2′ may be connected to the drain electrodes DE6 and DE6′ of the sixth transistors T6 and T6′ through the third contact holes CT3 and CT3′ penetrating through the interlayer insulating layer ILD and the gate insulating layer GIN.

On the data line DL, the first dummy data line DDL1, the second dummy data line DDL2, the initialization power line VIL, the first connection electrodes CNE1 and CNE1′, and the second connection electrodes CNE2 and CNE2′, a first passivation layer PAS1 may be disposed. The first passivation layer PAS1 may include an inorganic film.

A first via layer VA1 may be disposed on the first passivation layer PAS1. The first via layer VA1 may include an organic film made of an acryl resin, an epoxy resin, a phenolic resin, a polyamide resin, a polyimide resin, or the like.

Anode connection electrodes ACE and ACE′ may be disposed on the first via layer VA1. The anode connection electrodes ACE and ACE′ may be connected to the first connection electrodes CNE1 and CNE1′ through the fifth contact holes CT5 and CT5′ penetrating through the first via layer VA1 and the first passivation layer PAS1.

A second passivation layer PAS2 may be disposed on the anode connection electrodes ACE and ACE′. The second passivation layer PAS2 and the first passivation layer PAS1 described above may include a same material.

A second via layer VA2 may be disposed on the second passivation layer PAS2. The second via layer VA2 and the first via layer VA1 described above may include a same material.

A light emitting element layer EMTL may be disposed on the second via layer VA2. The light emitting element layer EMTL may include a pixel defining layer PDL and a light emitting element ED stacked in the third direction D3. In an embodiment, the light emitting element ED of each pixel may include anode electrodes AE and AE′, a light emitting layer EL, and a cathode electrode CE.

The anode electrodes AE and AE′ of each light emitting element ED described above may be disposed on the second via layer VA2. The anode electrodes AE and AE′ may be connected to the anode connection electrodes ACE and ACE′ through the sixth contact holes CT6 and CT6′ penetrating through the second via layer VA2 and the second passivation layer PAS2.

The light emitting areas EA and EA′ may be areas in which the anode electrodes AE and AE′, the light emitting layer EL, and the cathode electrode CE are sequentially stacked and holes from the anode electrodes AE and AE′ and electrons from the cathode electrode CE are recombined to each other in the light emitting layer EL to emit light.

In a top emission structure that emits light in a direction to the cathode electrode CE from the light emitting layer EL, the anode electrode may be formed of a single layer made of molybdenum (Mo), titanium (Ti), copper (Cu), or aluminum (Al) or be formed of a stacked structure (Ti/Al/Ti) of aluminum and titanium, a stacked structure (ITO/Al/ITO) of aluminum and ITO, an APC alloy, and a stacked structure (ITO/APC/ITO) of an APC alloy and ITO. The APC alloy may be an alloy of silver (Ag), palladium (Pd), and copper (Cu).

The pixel defining layer PDL may serve to define the light emitting areas EA and EA′ of the pixel. To this end, the pixel defining layer PDL may be disposed on the second via layer VA2 and expose a partial area of the anode electrodes AE and AE′ in a plan view. The pixel defining layer PDL may cover edges of the anode electrode AE and AE′. The pixel defining layer PDL may be formed of an organic film made of an acryl resin, an epoxy resin, a phenolic resin, a polyamide resin, a polyimide resin, or the like.

A light emitting layer EL may be disposed on the anode electrodes AE and AE′. The light emitting layer EL may include an organic material to emit light of a color. For example, the light emitting layer EL may include a hole transporting layer, an organic material layer, and an electron transporting layer. The organic material layer may include a host and a dopant. The organic material layer may include a material that emits light and may be formed of a phosphorescent material or a fluorescent material.

For example, the organic material layer of the light emitting layer EL that emits light of a first color (e.g., blue) may include a phosphorescent material including a host material such as CBP or mCP and including a dopant material such as (4,6-F2ppy)2Irpic or L2BD111, but the disclosure is not limited thereto.

The organic material layer of the light emitting layer EL that emits light of a second color (e.g., green) may include a phosphorescent material including a host material such as CBP or mCP and a dopant material such as Ir(ppy)3(fac tris(2-phenylpyridine) iridium). In another embodiment, the organic material layer of the light emitting layer EL that emits light of the second color may include a fluorescent material such as Alq3(tris(8-hydroxyquinolino)aluminum), but the disclosure is not limited thereto.

The organic material layer of the light emitting layer EL that emits light of a third color (e.g., red) may include a phosphorescent material including a host material such as carbazole biphenyl (CBP) or mCP(1,3-bis(carbazol-9-yl), and including a dopant containing at least one of PIQIr(acac) (bis(1-phenylisoquinoline) acetylacetonate iridium), PQIr(acac) (bis(1-phenylquinoline) acetylacetonate iridium), PQIr(tris(1-phenylquinoline) iridium), and PtOEP(octaethylporphyrin platinum). In another embodiment, the organic material layer of the light emitting layer EL that emits light of the third color may include a fluorescent material such as PBD:Eu(DBM)3(Phen) or perylene, but the disclosure is not limited thereto.

The cathode electrode CE may be disposed on the light emitting layer EL. The cathode electrode CE may cover the light emitting layer EL. The cathode electrode CE may be a common layer commonly disposed on the light emitting layers EL. A capping layer may be formed on the cathode electrode CE.

In the top emission structure, the cathode electrode CE may be formed of a transparent conductive material (TCO) such as ITO or IZO capable of transmitting light, or a semi-transmissive conductive material such as magnesium (Mg), silver (Ag), or an alloy of magnesium (Mg) and silver (Ag). In case that the cathode electrode is formed of a semi-transmissive conductive material, emission efficiency may be increased by forming a micro cavity.

The encapsulation layer ENC may be disposed on the light emitting element layer EMTL. The encapsulation layer ENC may include one or more inorganic films TFEL and TFE3 to prevent oxygen or moisture from permeating into the light emitting element layer EMTL. The encapsulation layer ENC may include at least one organic film to protect the light emitting element layer EMTL from foreign substances such as dust. For example, the encapsulation layer ENC may include a first encapsulation inorganic layer TFE1, an encapsulation organic layer TFE2, and a second encapsulation inorganic layer TFE3.

The first encapsulation inorganic layer TFE1 may be disposed on the cathode electrode CE, the encapsulation organic layer TFE2 may be disposed on the first encapsulation inorganic layer TFE1, and the second encapsulation inorganic layer TFE3 may be disposed on the encapsulation organic layer TFE2. The first encapsulation inorganic layer TFE1 and the second encapsulation inorganic layer TFE3 may be formed of a multi-film in which one or more inorganic films of a silicon nitride layer, a silicon oxynitride layer, a silicon oxide layer, a titanium oxide layer, and an aluminum oxide layer are alternately stacked each other. The encapsulation organic layer TFE2 may be an organic film made of an acrylic resin, an epoxy resin, a phenolic resin, a polyamide resin, or a polyimide resin.

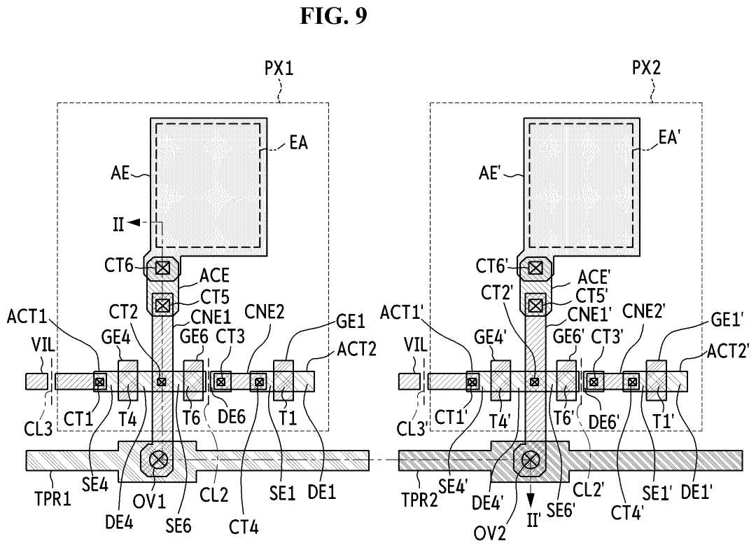

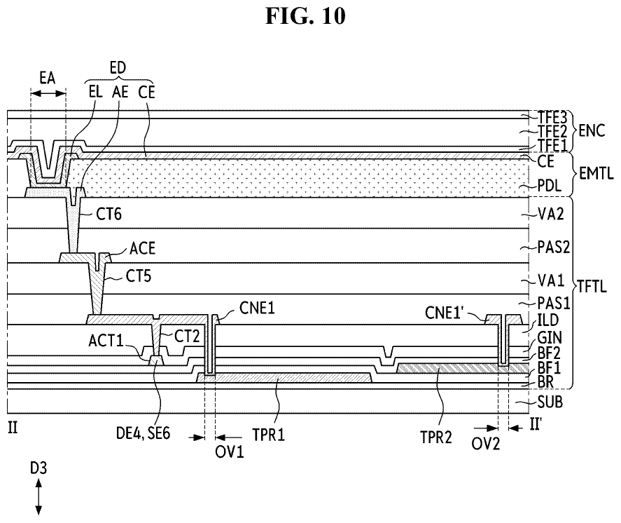

FIG. 9 is a schematic diagram of the display device manufactured according to the repair method according to an embodiment and FIG. 10 is a schematic cross-sectional view taken along line II-II′ of FIG. 9.

The display devices of FIGS. 9 and 10 may be different from the display devices of FIGS. 7 and 8 described above at least in that the initialization power line VIL and the first active layers ACT1 and ACT1′ are cut and the first connection electrodes CNE1 and CNE1′ and the repair lines TPR1 and TPR2 are connected. Therefore, such differences will be described as follows.

As illustrated in FIG. 9, the source electrodes of the sixth transistor T6 and T6′ may be cut along second cut line CL2 and CL2′. For example, in a plan view, the source electrodes SE6 and SE6′ of the sixth transistors T6 and T6′ may be disconnected along the second cut lines CL2 and CL2′ between the gate electrodes GE6 and GE6′ of the sixth transistor T6 and T6′ and the second connection electrodes CNE2 and CNE2′. According to an embodiment, as a laser beam is irradiated on the source electrodes SE6 and SE6′ of the sixth transistors T6 and T6′ along the second cut lines CL2 and CL2′, the source electrodes SE6 and SE6′ of the sixth transistors T6 and T6′ on the second cut lines CL2 and CL2′ may be cut.

As illustrated in FIG. 9, the initialization power line VIL may be cut along third cut lines CL3 and CL3′. According to an embodiment, as the laser beam is irradiated on the initialization power line VIL along the third cut lines CL3 and CL3′, the initialization power line VIL on the third cut lines CL3 and CL3′ may be cut. On the other hand, in contrast, the source electrodes SE4 and SE4′ of the fourth transistors T4 and T4′ may be disconnected between the gate electrodes GE4 and GE4′ of the fourth transistors T4 and T4′ and the initialization power line VIL.

As illustrated in FIGS. 9 and 10, since the first repair line TPR1 and the first connection electrode CNE1 of the first pixel PX1 overlap each other in a plan view in a first overlapping area OV1, the first repair line TPR1 and the first connection electrode CNE1 of the first pixel PX1 may be connected to each other in the first overlapping area OV1. For example, by irradiating a laser beam on the first connection electrode CNE1 in the first overlapping area OV1, the first connection electrode CNE1 and the first repair line TPR1 may be in contact (or in direct contact) with each other in the first overlapping area OV1. Accordingly, the anode electrode AE of the first pixel PX1 and the first dummy pixel DPX1 may be connected. For example, the anode electrode AE of the first pixel PX1 may be connected to the first dummy pixel DPX1 through the anode connection electrode ACE, the first connection electrode CNE1, and the first repair line TPR1. According to an embodiment, a groove may be formed in the first repair line TPR1 by the laser beam irradiated on the first overlapping area OV1.

As illustrated in FIGS. 9 and 10, since the second repair line TPR2 and the first connection electrode CNE1′ of the second pixel PX2 overlap each other in a plan view in a second overlapping area OV2, the second repair line TPR2 and the first connection electrode CNE1′ of the second pixel PX2 may be connected to each other in the second overlapping area OV2. For example, by irradiating a laser beam on the first connection electrode CNE1′ in the second overlapping area OV2, the first connection electrode CNE1′ and the second repair line TPR2 may be in contact (or in direct contact) with each other in the second overlapping area OV2. Accordingly, the anode electrode AE′ of the second pixel PX2 and the second dummy pixel DPX2 may be connected. For example, the anode electrode AE′ of the second pixel PX2 may be connected to the second dummy pixel DPX2 through the anode connection electrode ACE′, the first connection electrode CNE1′, and the second repair line TPR2. According to an embodiment, a groove may be formed in the second repair line TPR2 by the laser beam irradiated on the second overlapping area OV2.

Although not illustrated, the drain electrode of the second transistor T2 may be cut. For example, the drain electrode of the second transistor T2 may be cut between the gate electrode of the second transistor T2 and the data line DL. Accordingly, the second transistor T2 and the data line DL may be separated from each other.

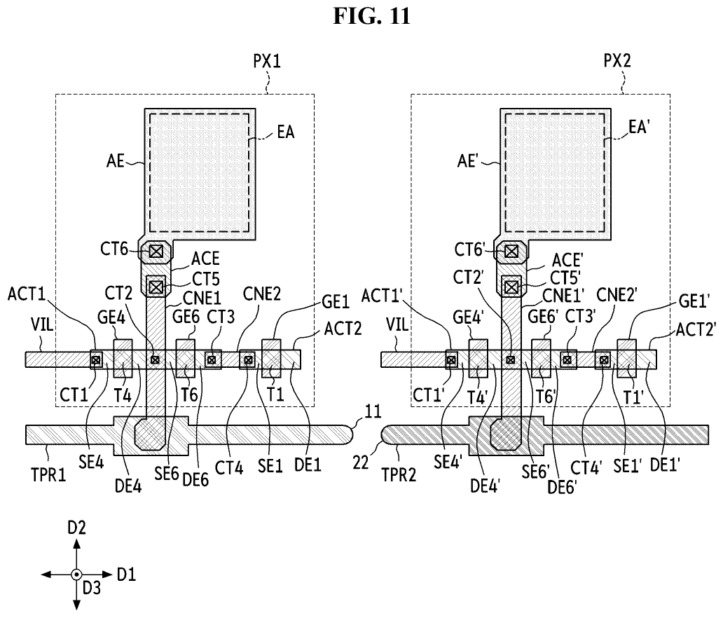

FIG. 11 is a schematic diagram of the display device 100 according to an embodiment.

The display device of FIG. 11 may be different from the display device 100 of FIGS. 7 and 8 described above in each shape of an end portion 11 of the first repair line TPR1 and an end portion 22 of the second repair line TPR2. Therefore, such a difference will be described as follows.

As illustrated in FIG. 11, at least one of the end portion 11 of the first repair line TPR1 and the end portion 22 of the second repair line TPR2 disposed adjacent to each other may have a round (or curved) shape. For example, the end portion 11 of the first repair line TPR1 and the end portion 22 of the second repair line TPR2 may each have a round shape. In a plan view, the end portion 11 of the first repair line TPR1 may have a round shape that convexly protrudes toward the end portion 22 of the second repair line TPR2, and the end portion 22 of the second repair line TPR2 may have a round shape that convexly protrudes toward the end portion of the first repair line TPR1.

In an embodiment, the first repair line TPR1 and the second repair line TPR2 of FIG. 11 may be disposed on different layers as in FIG. 8 described above.

As illustrated in FIG. 11, in case that the end portions 11 and 22 of the first repair line TPR1 and the second repair line TPR2 have the round shape, the concentration of electric fields in the end portions 11 and 22 may be minimized. Accordingly, the aforementioned static electricity prevention effect may be improved.

The display device according to the embodiment can be applied to various electronic devices. The electronic device according to one embodiment includes the display device described above and may further include modules or devices having additional functions in addition to the display device.

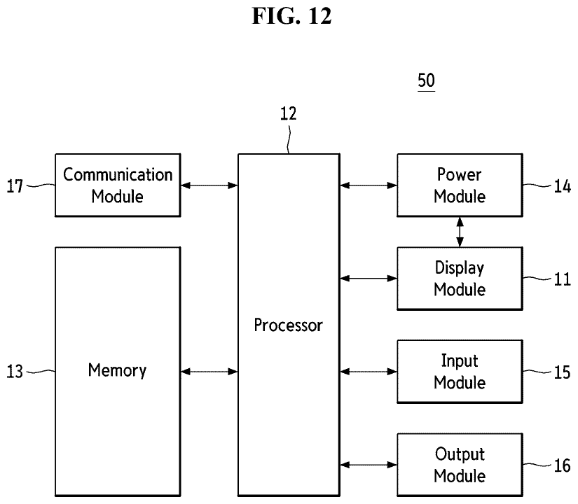

FIG. 12 is a block diagram of an electronic device according to one embodiment. Referring to FIG. 12, the electronic device 50 according to one embodiment may include a display module, a processor 12, a memory 13, and a power module 14. The electronic device 5000 may further include an input module 14, a non-image output module 15 and/or a communication module 16.

The electronic device 50 may output various information in the form of images through the display module 11. When the processor 12 executes an application stored in the memory 13, image information provided by the application may be provided to the user through the display module 1100. The power module 14 may include a power supply module such as a power adapter or a battery device, and a power conversion module that converts the power supplied by the power supply module to generate power required for the operation of the electronic device 5000. The input module 14 may provide input information to the processor 12 and/or the display module 11. The non-image output module 15 may receive information other than images transmitted from the processor 12, such as sound, haptics, and light, and provide the information to the user. The communication module 16 is a module that is responsible for transmitting and receiving information between the electronic device 5000 and an external device, and may include a receiving unit and a transmitting unit.

At least one of the components of the electronic device 50 described above may be included in the display device according to the embodiments described above. In addition, some of the individual modules functionally included in one module may be included in the display device, and others may be provided separately from the display device. For example, the display device includes a display module 11, and the processor 12, memory 13, and power module 14 may be provided in the form of other devices within the electronic device 11 other than the display device.

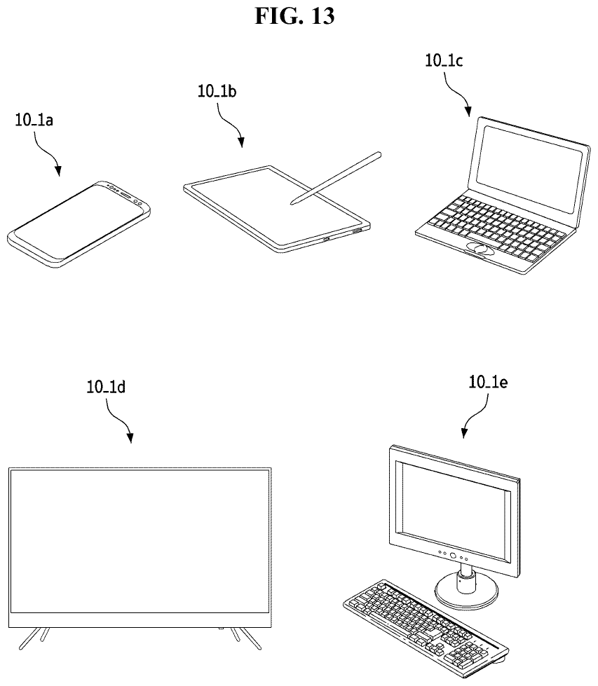

FIGS. 13, 14, and 15 are schematic diagrams of electronic devices according to various embodiments. FIGS. 13 to 15 illustrate examples of various electronic devices to which the display device according to the embodiments is applied.

FIG. 13 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they also include display modules and input modules similar to smartphones 10_1, and may additionally include communication modules in some cases.

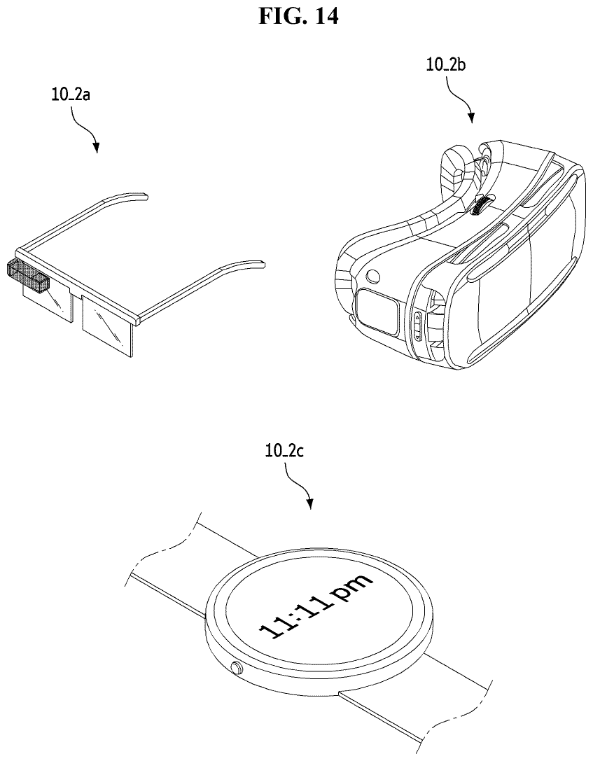

FIG. 14 shows an example of an electronic device including a display module being applied to a wearable electronic device. The wearable electronic device may be a smart glasses 10_2a, a head-mounted display 10_2b, a smart watch 10_2c, etc.

The smart glasses 10_2a and the head-mounted display 10_2b may include a display module that emits a display image and a reflector that reflects the emitted display screen and provides it to the user's eyes, thereby providing a virtual reality or augmented reality screen to the user.

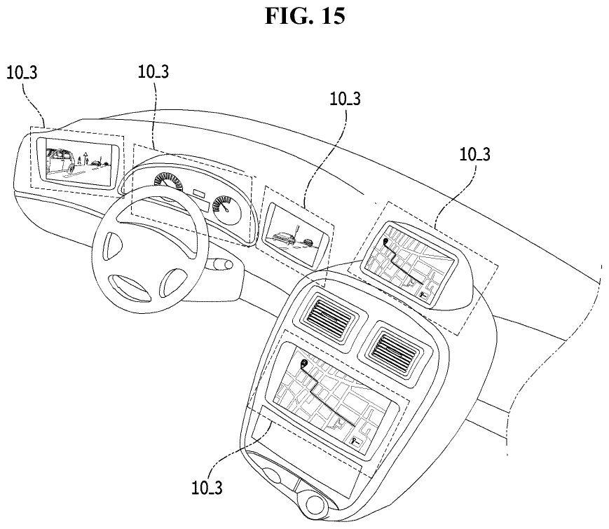

The smart watch 10_2c includes a biometric sensor as an input device, and may provide biometric information recognized by the biometric sensor to the user through the display module. FIG. 15 illustrates a case where an electronic device including a display module is applied to a vehicle. For example, the electronic device 10_3 may be applied to a dashboard, center fascia, etc. of a vehicle, or may be applied to a CID (Center Information Display) placed on a dashboard of a vehicle, or a room mirror display replacing a side mirror.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a first anode electrode and a second anode electrode on a substrate;
a first light emitting layer on the first anode electrode and a second light emitting layer on the second anode electrode;
a common electrode on the first light emitting layer and the second light emitting layer;
a first connection electrode connected to the first anode electrode;
a second connection electrode connected to the second anode electrode;
a first repair line overlapping the first connection electrode in a plan view; and
a second repair line overlapping the second connection electrode in a plan view,
wherein the first repair line and the second repair line are disposed on different layers.

2. The display device of claim 1, further comprising:
an insulating layer between the first repair line and the second repair line.

3. The display device of claim 1, wherein in a plan view, an end portion of the first repair line and an end portion of the second repair line face each other.

4. The display device of claim 1, wherein the first repair line is disposed closer to the substrate than the second repair line.

5. The display device of claim 1, wherein a distance between the substrate and the second repair line is greater than a distance between the substrate and the first repair line.

6. The display device of claim 1, wherein a number of insulating layers between the substrate and the second repair line is greater than a number of insulating layers between the substrate and the first repair line.

7. The display device of claim 1, wherein in a plan view, the first repair line and the second repair line do not overlap.

8. The display device of claim 1, wherein in an area the first repair line and the first connection electrode overlap each other in a plan view, the first repair line and the first connection electrode are connected to each other.

9. The display device of claim 1, wherein in an area the second repair line and the second connection electrode overlap each other in a plan view, the second repair line and the second connection electrode are connected to each other.

10. The display device of claim 1, wherein at least one of an end portion of the first repair line and an end portion of the second repair line has a round shape.

11. The display device of claim 10, wherein in a plan view, the end portion of the first repair line has a round shape that convexly protrudes toward the end portion of the second repair line.

12. The display device of claim 10, wherein in a plan view, the end portion of the second repair line has a round shape that convexly protrudes toward the end portion of the first repair line.

13. The display device of claim 1, further comprising:
a first dummy pixel connected to the first repair line.

14. The display device of claim 13, wherein the first dummy pixel is disposed in a non-display area of the substrate.

15. The display device of claim 14, wherein
the first repair line is disposed in a display area of the substrate,
the first repair line extends to the non-display area of the substrate, and
the first repair line is connected to the first dummy pixel in the non-display area of the substrate.

16. The display device of claim 13, further comprising:
a first dummy data line connected to the first dummy pixel.

17. The display device of claim 13, wherein the first dummy pixel does not include a light emitting element.

18. The display device of claim 1, further comprising:
a second dummy pixel connected to the second repair line.

19. The display device of claim 18, wherein
the second dummy pixel is disposed in a non-display area of the substrate,
the second repair line is disposed in a display area of the substrate,
the second repair line extends to the non-display area of the substrate, and
the second repair line is connected to the second dummy pixel in the non-display area of the substrate.

20. An electronic device, comprising:
a display device that provides an image; and
a processor that transmits an image data signal to the display device, wherein
the display device comprises:
a first anode electrode and a second anode electrode on a substrate;
a first light emitting layer on the first anode electrode and a second light emitting layer on the second anode electrode;
a common electrode on the first light emitting layer and the second light emitting layer;
a first connection electrode connected to the first anode electrode;
a second connection electrode connected to the second anode electrode;
a first repair line overlapping the first connection electrode in a plan view; and
a second repair line overlapping the second connection electrode in a plan view, and
the first repair line and the second repair line are disposed on different layers.
